(19) United States
(12) Patent Application Publication
(10) Pub. No.: US 2026/0243633 A1
(43) Pub. Date: Aug. 20, 2026

(54) ATOMIZER EQUIPMENT AND LIQUID PARTICLE DETECTION SYSTEM USING THE SAME

(71) Applicant: INNOVATIVE NANOTECH INCORPORATED, Hsinchu City (TW)

(72) Inventors: Hsin-Chia Ho, Hsinchu City (TW); Huang-Di Lin, Hsinchu City (TW); Chih-Hao Ting, Hsinchu City (TW); Yen-Liang Lin, Hsinchu City (TW)

(73) Assignee: INNOVATIVE NANOTECH INCORPORATED, Hsinchu City (TW)

(21) Appl. No.: 19/439,106

(22) Filed: Jan. 2, 2026

(30) Foreign Application Priority Data
Feb. 14, 2025 (TW) 114105645

(51) Int. Cl. G01N 1/34; G01N 1/14

(52) U.S. Cl. CPC G01N 1/34; G01N 1/14; G01N 2001/1463

(57) ABSTRACT

An atomizer equipment includes a gas storage tank, a cleaning liquid storage tank, and an atomization chamber. The atomization chamber includes a gas flow injection port, a to-be-tested liquid inlet, an impact plate, an aerogel outlet, a cleaning liquid injection port, and a liquid discharge port. When a clean dry gas flow is introduced into the atomization chamber through the gas flow injection port, a to-be-tested liquid in a to-be-tested liquid tank is drawn into the atomization chamber and mixed with the clean dry gas flow to form an aerogel. Part of the aerogel collides with the impact plate and condenses into a condensate. When the gas flow injection port and the to-be-tested liquid inlet are controlled to stop introducing the clean dry gas and the to-be-tested liquid, the cleaning liquid is introduced through the cleaning liquid injection port and flushes toward the impact plate.

### CROSS-REFERENCE TO RELATED APPLICATION

This non-provisional application claims priority under 35 U.S.C. § 119(a) to Patent Application No. 114105645 filed in Taiwan, R.O.C. on February 14, 2025, the entire contents of which are hereby incorporated by reference.

### BACKGROUND

### Technical Field

The present invention relates to the field of detection, and in particular, to an atomizer equipment and a liquid particle detection system using the same.

### Related Art

With the advancement of Moore's Law, feature sizes of semiconductor devices are miniaturized, and semiconductor manufacturers are implementing increasingly stringent control over particles in all devices and environments. For example, for semiconductor devices with a line width of 12 nanometers, particles of approximately 6 nanometers may cause defects.

To improve product yield, all factors that may generate particles during semiconductor manufacturing need to be controlled, for example, process liquids used in the processes, such as deionized water for cleaning, hydrochloric acid, and hydrogen peroxide.

Currently, the common practice for detecting these process liquids is to use a single detection system to monitor each individual process liquid. When a quantity of particles is determined to be excessive, the detection system may issue a warning to notify personnel for handling.

At present, a common problem found during the handling is that crystallization tends to occur near a position where the process liquid is introduced after a period of operation, leading to excessive particles during testing. Such conditions can mostly be resolved through disassembly and cleaning. In other words, the particles in the process solution do not exceed the standard. Instead, the problem arises from contamination caused by crystallization inside the detection device. Since testing and troubleshooting require manual disassembly of the testing device for inspection, shutdown for inspection is necessary, resulting in a process interruption, or the use of untested process liquids in some product may pose a risk.

### SUMMARY

To resolve the foregoing problem, an atomizer equipment is provided herein. The atomizer equipment includes a gas storage tank, a cleaning liquid storage tank, and an atomization chamber. The gas storage tank is configured to store clean dry gas. The cleaning liquid storage tank is configured to store a cleaning liquid. The atomization chamber includes a gas flow injection port, a to-be-tested liquid inlet, an impact plate, an aerogel outlet, a cleaning liquid injection port, and a liquid discharge port.

The gas flow injection port is on a side of the atomization chamber, connected to the gas storage tank through a first control valve, and configured to introduce a clean dry gas flow. The to-be-tested liquid inlet is on a bottom of the atomization chamber and connected to a to-be-tested liquid tank through a second control valve. When the first control valve and the second control valve are opened, the clean dry gas flow is introduced into the atomization chamber through the gas flow injection port, a to-be-tested liquid in the to-be-tested liquid tank is drawn into the atomization chamber, and the to-be-tested liquid and the clean dry gas flow are mixed to form an aerogel. The impact plate is in the atomization chamber and faces the gas flow injection port. Part of the aerogel collides with the impact plate and condenses into a condensate.

The aerogel outlet is on an upper end of the atomization chamber. The remaining aerogel in the atomization chamber is outputted along the aerogel outlet. The cleaning liquid injection port is on a side of the atomization chamber, connected to the cleaning liquid storage tank through a third control valve, and configured for injection of the cleaning liquid. The liquid discharge port is on a bottom of the atomization chamber, and configured to discharge the condensate or the cleaning liquid. When the first control valve and the second control valve are controlled to be closed and the third control valve is controlled to be opened, the cleaning liquid flushes toward the impact plate.

In some embodiments, opening or closing of the liquid discharge port is controlled through a fourth control valve.

In some embodiments, the cleaning liquid injection port is on a same side as the gas flow injection port. Further, in some embodiments, a non-right angle is formed between a direction of a cleaning liquid flow generated from the cleaning liquid injection port and an extension direction of the impact plate.

In some embodiments, the cleaning liquid injection port is on an opposite side of the gas flow injection port.

In some embodiments, the second control valve is a rotary control valve, including a to-be-tested liquid channel and a cleaning liquid channel, the second control valve is further connected to the cleaning liquid storage tank through the cleaning liquid channel, and when the first control valve and the to-be-tested liquid channel are controlled to be closed, and the cleaning liquid channel is opened, the cleaning liquid is injected into the atomization chamber through the to-be-tested liquid inlet to clean the gas flow injection port.

In some embodiments, a hydraulic pressure of the cleaning liquid injected through the cleaning liquid injection port or the to-be-tested liquid inlet ranges from 0.2 Kg/cm² to 5 Kg/cm².

In some embodiments, a flow rate of the clean dry gas flow ranges from 2L to 10L per minute.

In some embodiments, the cleaning liquid is deionized water, isopropyl alcohol, hydrogen peroxide, or hydrochloric acid.

A liquid particle detection system is further provided herein. The liquid particle detection system includes a to-be-tested liquid tank, an atomizer equipment, a control apparatus, a dryer, an electrostatic neutralization chamber, a particle separator, and a counter. The to-be-tested liquid tank stores a to-be-tested liquid. The atomizer equipment is connected to the to-be-tested liquid tank as described above. The control apparatus is electrically connected to the atomizer equipment to control opening or closing of a first control valve, a second control valve, and a third control valve in the atomizer equipment. The dryer is connected to an aerogel outlet of the atomizer equipment to heat and dry an aerogel. The electrostatic neutralization chamber is connected to the dryer, and is configured to receive the dried aerogel and electrostatically neutralize the aerogel. The particle separator is connected to the electrostatic neutralization chamber to receive the electrostatically neutralized aerogel, and configured to separate a plurality of particles in the aerogel based on particle sizes through control of an electric field and a flow field. The counter is connected to the particle separator and electrically connected to the control apparatus, and configured to coagulate and amplify separated particles, calculate and determine a quantity of the particles, and transmit counting information to the control apparatus.

As described in the foregoing embodiments, the cleaning liquid injection port and the liquid discharge port are provided, so that when a warning occurs, the system can first be controlled to automatically clean the impact plate, and preliminarily perform troubleshooting for faults caused by the drying and crystallization of the liquid, thereby enabling rapid resumption of monitoring and greatly reducing the downtime for maintenance.

### BRIEF DESCRIPTION OF THE DRAWINGS

FIG. 1 is a block diagram of a first embodiment of an atomizer equipment.

FIG. 2 is a schematic diagram of a partial cross section of a first embodiment of an atomizer equipment.

FIG. 3 is a schematic diagram of a partial cross section of a second embodiment of an atomizer equipment.

FIG. 4 is a schematic diagram of a partial cross section of a third embodiment of an atomizer equipment.

FIG. 5 is a block diagram of an embodiment of a liquid particle detection system.

### DETAILED DESCRIPTION

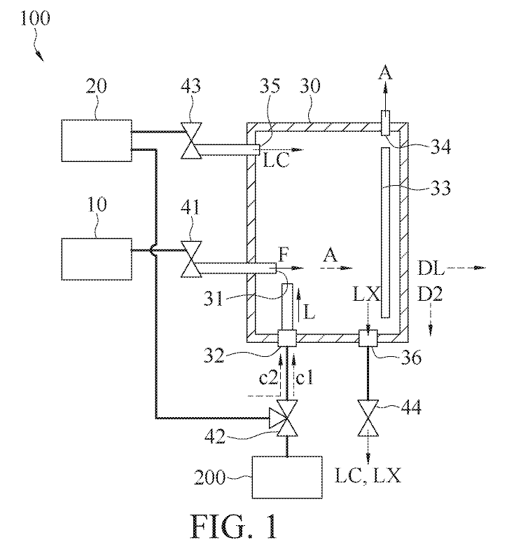

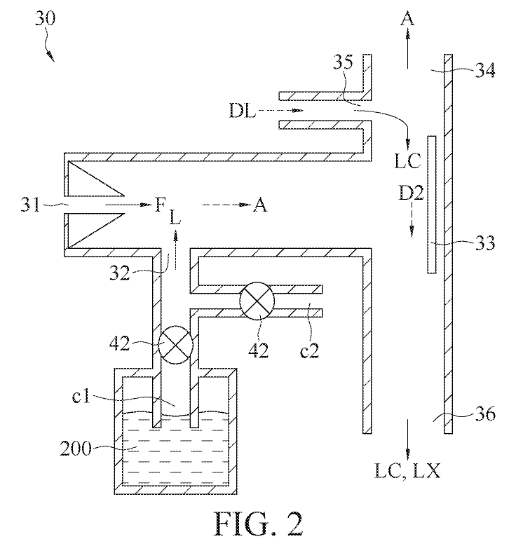

FIG. 1 is a block diagram of a first embodiment of an atomizer equipment. FIG. 2 is a schematic diagram of a partial cross section of a first embodiment of an atomizer equipment.

As shown in FIG. 1 and FIG. 2, an atomizer equipment 100 includes a gas storage tank 10, a cleaning liquid storage tank 20, and an atomization chamber 30. The gas storage tank 10 stores clean dry gas, such as clean dry air (CDA), clean dry nitrogen, or clean dry inert gas. The cleaning liquid storage tank 20 stores a cleaning liquid LC, which can be used with various process raw materials. The cleaning liquid LC may be deionized water, hydrochloric acid, hydrogen peroxide, isopropyl alcohol, or the like.

The atomization chamber 30 includes a gas flow injection port 31, a to-be-tested liquid inlet 32, an impact plate 33, an aerogel outlet 34, a cleaning liquid injection port 35, and a liquid discharge port 36. The gas flow injection port 31 is on a side of the atomization chamber 30, connected to the gas storage tank 10 through a first control valve 41, and configured to introduce a clean dry gas flow F. For example, in some embodiments, a flow rate of the clean dry gas flow F ranges from 2L to 10L per minute.

The to-be-tested liquid inlet 32 is on a bottom of the atomization chamber 30 and connected to a to-be-tested liquid tank 200 through a second control valve 42. When the first control valve 41 and the second control valve 42 are opened, and the clean dry gas flow F is introduced into the atomization chamber 30 through the gas flow injection port 31, a negative pressure is generated, a to-be-tested liquid L in the to-be-tested liquid tank 200 is drawn into the atomization chamber 30, and the to-be-tested liquid L and the clean dry gas flow F are mixed to form an aerogel A. The impact plate 33 is in the atomization chamber 30 and faces the gas flow injection port 31. Part of the aerogel A collides with the impact plate 33 and condenses into a condensate LX. The aerogel outlet 34 is on an upper end of the atomization chamber 30. The remaining aerogel A in the atomization chamber 30 is outputted to a subsequent device along the aerogel outlet 34 for detection of particles contained in the aerogel A.

The cleaning liquid injection port 35 is on a side of the atomization chamber 30 and connected to the cleaning liquid storage tank 20 through a third control valve 43 for injection of the cleaning liquid LC. The liquid discharge port 36 is on a bottom of the atomization chamber 30 and configured to discharge the condensate LX or the cleaning liquid LC. When the first control valve 41 and the second control valve 42 are controlled to be closed and the third control valve 43 is controlled to be opened, the cleaning liquid LC flushes toward the impact plate 33. Generally speaking, a pressure of the cleaning liquid LC when introduced is greater than a pressure of the to-be-tested liquid L when introduced through the to-be-tested liquid inlet 32, so as to clean the impact plate 33 and remove crystalline particles generated after residues of the aerogel A on the impact plate 33 dry out. For example, a hydraulic pressure of the cleaning liquid LC injected through the cleaning liquid injection port 35 or the to-be-tested liquid inlet 32 ranges from 0.2 Kg/cm² to 5 Kg/cm².

In more detail, in this embodiment, the cleaning liquid injection port 35 is on a same side as the gas flow injection port 31. Therefore, the atomization chamber 30 is further provided with the cleaning liquid injection port 35 and the liquid discharge port 36, so that when a warning occurs, the system can first be controlled to automatically clean the impact plate 33, and preliminarily perform troubleshooting for faults caused by the drying and crystallization of the liquid, thereby enabling rapid resumption of monitoring and greatly reducing the downtime for maintenance.

Studies have shown that part of the to-be-tested liquid L may also leave residues near the cleaning gas flow injection port 31 during negative pressure suction, thereby affecting the overall particle count. Referring to FIG. 1 and FIG. 2 again, in some embodiments, the second control valve 42 is a rotary control valve, including a to-be-tested liquid channel c1 and a cleaning liquid channel c2. The to-be-tested liquid channel c1 is connected to the to-be-tested liquid tank 200, and the cleaning liquid channel c2 is connected to the cleaning liquid storage tank 20. When the first control valve 41 is controlled to be closed, the to-be-tested liquid channel c1 is closed, and the cleaning liquid channel c2 is opened, the cleaning liquid LC is first drawn into the to-be-tested liquid inlet 32 and then injected into the atomization chamber 30, so as to clean the gas flow injection port 31.

Further, in some embodiments, opening or closing of the liquid discharge port 36 is controlled through a fourth control valve 44. Generally, during the general measurement of the to-be-tested liquid L, the fourth control valve 44 is controlled to close the liquid discharge port 36. When the condensate LX accumulates to a certain amount, or during the injection of the cleaning liquid LC, the fourth control valve 44 is controlled to open the liquid discharge port 36. The accumulated amount of the condensate LX may be sensed through a liquid level sensor.

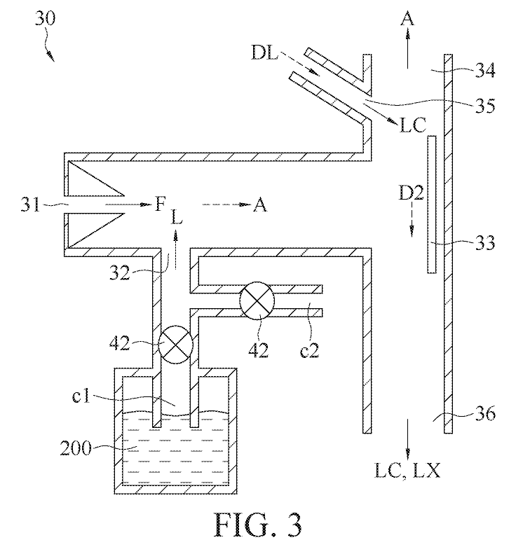

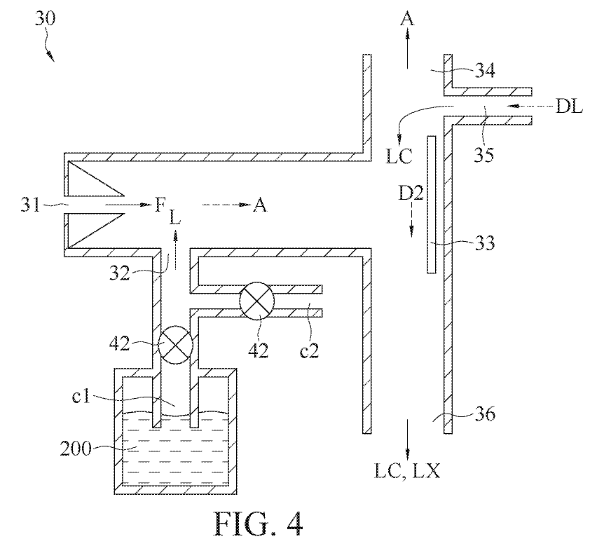

FIG. 3 is a schematic diagram of a partial cross section of a second embodiment of an atomizer equipment. FIG. 4 is a schematic diagram of a partial cross section of a third embodiment of an atomizer equipment. As shown in FIG. 3 and FIG. 4, and with reference to FIG. 2 together, a main difference between the second embodiment and the third embodiment and the first embodiment lies in a position of a cleaning liquid injection port 35. As shown in FIG. 3, a non-right angle is formed between a flow direction DL of a cleaning liquid generated through the cleaning liquid injection port 35 and an extension direction D2 of the impact plate 33. This is an angle adjustment to inject the cleaning liquid LC toward the impact plate 33, so that a water pressure can be further reduced to avoid splashing. As shown in FIG. 4, the cleaning liquid injection port 35 is on an opposite side of the gas flow injection port 31, so that the cleaning liquid LC flows down from above the impact plate 33 for cleaning. The first to third embodiments may be adjusted based on crystalline properties of different to-be-tested liquids L.

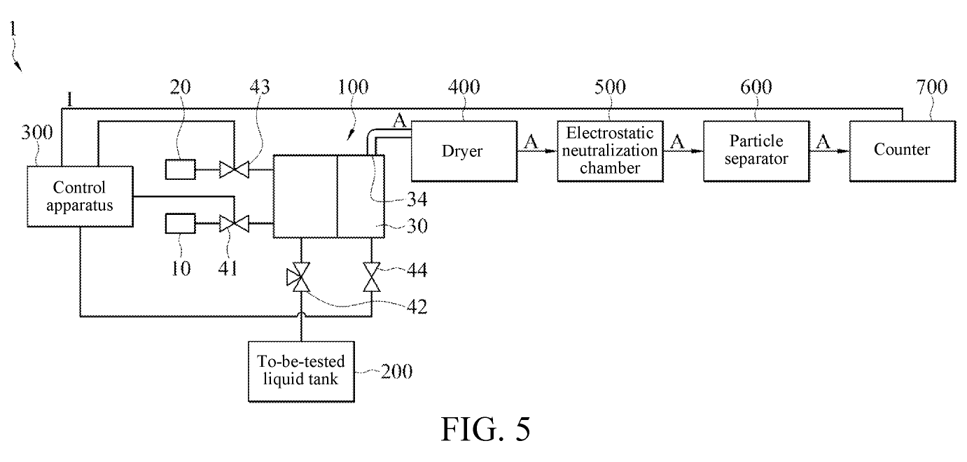

FIG. 5 is a block diagram of an embodiment of a liquid particle detection system. As shown in FIG. 5, a liquid particle detection system 1 is briefly described herein. The liquid particle detection system includes an atomizer equipment 100, a to-be-tested liquid tank 200, a control apparatus 300, a dryer 400, an electrostatic neutralization chamber 500, a particle separator 600, and a counter 700. The to-be-tested liquid tank 200 stores a to-be-tested liquid L. A detailed structure of the atomizer equipment 100 is as described in the previous embodiments, and details are not described herein again. The atomizer equipment 100 is connected to the to-be-tested liquid tank 200. The control apparatus 300 is electrically connected to the atomizer equipment 100 to control opening or closing of a first control valve 41, a second control valve 42, a third control valve 43, and/or a fourth control valve 44 in the atomizer equipment 100, thereby determining a detection mode or a cleaning mode of the atomizer equipment 100.

The dryer 400 is connected to an aerogel outlet 34 of the atomizer equipment 100 to heat and dry an aerogel A. The electrostatic neutralization chamber 500 is connected to the dryer 400, and is configured to receive the dried aerogel A and electrostatically neutralize the aerogel A through X-rays, or the like. The particle separator 600 is connected to the electrostatic neutralization chamber 500 to receive the electrostatically neutralized aerogel A, and configured to separate a plurality of particles in the aerogel A based on particle sizes through control of an electric field and a flow field. The counter 700 is connected to the particle separator 600 and electrically connected to the control apparatus 300, coagulates and amplifies separated particles, calculates and determines a quantity of the particles, and transmits counting information I to the control apparatus 300. Further, the control apparatus 300 determines whether to simultaneously start a warning apparatus to notify factory personnel to perform maintenance, that is, to clean the atomizer equipment 100.

Based on the above, the cleaning liquid injection port 35 and the liquid discharge port 36 are provided on the atomization chamber 30 of the atomizer equipment 100, so that when a warning occurs, the system can first be controlled to automatically clean the impact plate 33, and preliminarily perform troubleshooting for faults caused by the drying and crystallization of the liquid, thereby enabling rapid resumption of monitoring and greatly reducing the downtime for maintenance.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An atomizer equipment, comprising:
a gas storage tank configured to store clean dry gas;
a cleaning liquid storage tank configured to store a cleaning liquid; and
an atomization chamber, comprising:
a gas flow injection port on a side of the atomization chamber, connected to the gas storage tank through a first control valve, and configured to introduce a clean dry gas flow;
a to-be-tested liquid inlet on a bottom of the atomization chamber and connected to a to-be-tested liquid tank through a second control valve, wherein the clean dry gas flow is introduced into the atomization chamber through the gas flow injection port, a to-be-tested liquid in the to-be-tested liquid tank is drawn into the atomization chamber, and the to-be-tested liquid and the clean dry gas flow are mixed to form an aerogel when the first control valve and the second control valve are opened;
an impact plate in the atomization chamber and facing the gas flow injection port, wherein part of the aerogel collides with the impact plate and condenses into a condensate;
an aerogel outlet on an upper end of the atomization chamber, wherein the remaining aerogel in the atomization chamber is outputted along the aerogel outlet;
a cleaning liquid injection port on a side of the atomization chamber, connected to the cleaning liquid storage tank through a third control valve, and configured for injection of the cleaning liquid; and
a liquid discharge port on a bottom of the atomization chamber, and configured to discharge the condensate or the cleaning liquid,
wherein the cleaning liquid flushes toward the impact plate when the first control valve and the second control valve are controlled to be closed and the third control valve is controlled to be opened.

2. The atomizer equipment according to claim 1, wherein opening or closing of the liquid discharge port is controlled through a fourth control valve.

3. The atomizer equipment according to claim 1, wherein the cleaning liquid injection port is on a same side as the gas flow injection port.

4. The atomizer equipment according to claim 3, wherein a non-right angle is formed between a direction of a cleaning liquid flow generated from the cleaning liquid injection port and an extension direction of the impact plate.

5. The atomizer equipment according to claim 1, wherein the cleaning liquid injection port is on an opposite side of the gas flow injection port.

6. The atomizer equipment according to claim 1, wherein the second control valve is a rotary control valve, comprising a to-be-tested liquid channel and a cleaning liquid channel, the second control valve is further connected to the cleaning liquid storage tank through the cleaning liquid channel, and when the first control valve and the to-be-tested liquid channel are controlled to be closed, and the cleaning liquid channel is opened, the cleaning liquid is injected into the atomization chamber through the to-be-tested liquid inlet to clean the gas flow injection port.

7. The atomizer equipment according to claim 6, wherein a hydraulic pressure of the cleaning liquid injected through the cleaning liquid injection port or the to-be-tested liquid inlet ranges from 0.2 Kg/cm² to 5 Kg/cm².

8. The atomizer equipment according to claim 1, wherein a flow rate of the clean dry gas flow ranges from 2L to 10L per minute.

9. The atomizer equipment according to claim 1, wherein the cleaning liquid is deionized water, isopropyl alcohol, hydrogen peroxide, or hydrochloric acid.

10. A liquid particle detection system, comprising:
a to-be-tested liquid tank, storing a to-be-tested liquid;
the atomizer equipment according to claim 1, connected to the to-be-tested liquid tank;
a control apparatus, electrically connected to the atomizer equipment to control opening or closing of the first control valve, the second control valve, and the third control valve in the atomizer equipment;
a dryer, connected to the aerogel outlet of the atomizer equipment to heat and dry the aerogel;
an electrostatic neutralization chamber, connected to the dryer, and configured to receive the dried aerogel and electrostatically neutralize the aerogel;
a particle separator, connected to the electrostatic neutralization chamber to receive the electrostatically neutralized aerogel, and configured to separate a plurality of particles in the aerogel based on particle sizes through control of an electric field and a flow field; and
a counter, connected to the particle separator and electrically connected to the control apparatus, and configured to coagulate and amplify separated particles, calculate and determine a quantity of the particles, and transmit counting information to the control apparatus.

11. The liquid particle detection system according to claim 10, wherein opening or closing of the liquid discharge port is controlled through a fourth control valve.

12. The liquid particle detection system according to claim 10, wherein the cleaning liquid injection port is on a same side as the gas flow injection port.

13. The liquid particle detection system according to claim 12, wherein a non-right angle is formed between a direction of a cleaning liquid flow generated from the cleaning liquid injection port and an extension direction of the impact plate.

14. The liquid particle detection system according to claim 10, wherein the cleaning liquid injection port is on an opposite side of the gas flow injection port.

15. The liquid particle detection system according to claim 10, wherein the second control valve is a rotary control valve, comprising a to-be-tested liquid channel and a cleaning liquid channel, the second control valve is further connected to the cleaning liquid storage tank through the cleaning liquid channel, and when the first control valve and the to-be-tested liquid channel are controlled to be closed, and the cleaning liquid channel is opened, the cleaning liquid is injected into the atomization chamber through the to-be-tested liquid inlet to clean the gas flow injection port.

16. The liquid particle detection system according to claim 15, wherein a hydraulic pressure of the cleaning liquid injected through the cleaning liquid injection port or the to-be-tested liquid inlet ranges from 0.2 Kg/cm² to 5 Kg/cm².

17. The liquid particle detection system according to claim 10, wherein a flow rate of the clean dry gas flow ranges from 2L to 10L per minute.

18. The liquid particle detection system according to claim 10, wherein the cleaning liquid is deionized water, isopropyl alcohol, hydrogen peroxide, or hydrochloric acid.
